(19) United States
(12) Patent Application Publication
(10) Pub. No.: US 2025/0146965 A1
(43) Pub. Date: May 8, 2025

(54) SENSOR MODULE AND MANUFACTURING METHOD OF THE SAME

(71) Applicant: Electronics and Telecommunications Research Institute, Daejeon (KR)

(72) Inventors: Seungeon MOON, Daejeon (KR); Jeong Hun KIM, Daejeon (KR); Jong Pil IM, Daejeon (KR)

(73) Assignee: Electronics and Telecommunications Research Institute, Daejeon (KR)

(21) Appl. No.: 18/936,352

(22) Filed: Nov. 4, 2024

(30) Foreign Application Priority Data
Nov. 7, 2023 (KR) 10-2023-0153125
Jul. 18, 2024 (KR) 10-2024-0095141

(51) Int. Cl. G01N 27/12; B81B 7/02; G01N 27/14

(52) U.S. Cl. CPC G01N 27/121; B81B 7/02; G01N 27/14; B81B 2203/0353

(57) ABSTRACT

Provided is a sensor module and a manufacturing method of the same. The sensor module includes a substrate having a first region, a second region, and a third region, an insulation layer provided on the substrate, a temperature sensor layer provided in the insulation layer of the first region, a gas sensor layer provided in an upper portion of and inside the insulation layer of the second region adjacent to the temperature sensor layer, and being thicker than the temperature sensor layer, and a sensor module provided on the insulation layer of the third region adjacent to the gas sensor layer, and including a humidity sensor layer thinner than the gas sensor layer.

### CROSS-REFERENCE TO RELATED APPLICATIONS

This U.S. non-provisional patent application claims priority under 35 U.S.C. § 119 of Korean Patent Application Nos. 10-2023-0153125, filed on Nov. 7, 2023, and 10-2024-0095141, filed on Jul. 18, 2024, the entire contents of which are hereby incorporated by reference.

### BACKGROUND

The present disclosure herein relates to a sensor and a manufacturing method of the same, and more particularly, to a sensor module including a gas sensor, and a manufacturing method of the same.

A semiconductor-type gas sensor, which is the most commonly used sensor among various gas sensors, generally uses metal oxide powder deposited by a method such as screen printing as a sensing material, wherein the major factor of a gas sensing principle is a chemical reaction such as electron exchange between the above-described deposited gas sensing material and a target gas, and the reaction usually occurs at a high temperature of 200° C. to 500° C. In the case of a typical bulk-type gas sensor, heating is performed to the above-described operation temperature though a metal thick film-based heater behind a substrate such as alumina, the sensor usually shows a characteristic of consuming electric power of hundreds of mW. Compared to physical sensors such as acceleration and temperature sensors and chemical sensors such as humidity sensors, gas sensors having the above-described characteristic of consuming a large amount of electric power are difficult to be installed in products for various services in the era of IoT and wearables, so that research has been variously conducted on a sensor module capable of reducing the power consumption by 1/10 or less by applying partial heating, a heat loss minimization structure, or the like while reducing the size of a heater by using MEMS technology, wherein as the next-generation gas sensor, the sensor module is ultra small compared to a typical bulk gas sensor, but is able to be operated with low power, in addition to being able to be mass-produced using a CMOS-compatible MEMS process.

### SUMMARY

The present disclosure provides a sensor module capable of increasing and maximizing the reliability of gas sensing.

An embodiment of the inventive concept provides a sensor module. The sensor module includes a substrate having a first region, a second region, and a third region, an insulation layer provided on the substrate, a temperature sensor layer provided in the insulation layer of the first region, a gas sensor layer provided in an upper portion of and inside the insulation layer of the second region adjacent to the temperature sensor layer, and being thicker than the temperature sensor layer, and a humidity sensor provided on the insulation layer of the third region adjacent to the gas sensor layer, the humidity sensor layer thinner than the gas sensor layer.

In an embodiment, the substrate may have a first recess provided in the second region, wherein the gas sensor layer may be provided in the first recess.

In an embodiment, the insulation layer may include a first membrane provided on the first recess, and defined by a first MEMS hole exposing a portion of an edge of the first recess. In an embodiment, the sensor module may further includes heater electrodes provided in the first membrane, lower electrodes provided in the first membrane on the heater electrodes, and upper electrodes provided in the first membrane on the lower electrodes.

In an embodiment, the gas sensor layer may include a first lower sensor layer on a lower surface of the first membrane, and a first upper sensor layer on an upper surface of the first membrane.

In an embodiment, the first membrane may have a first via hole provided on the center of the first recess

In an embodiment, the gas sensor layer may further include a first middle sensor layer provided in the first via hall.

In an embodiment, the first membrane may include a lower insulation layer on the substrate, a supporting layer on the lower insulation layer, and first to fourth upper insulation layers on the supporting layer.

In an embodiment, the insulation layer may have a second recess provided in the third region.

In an embodiment, the humidity sensor layer may be provided in the second recess.

In an embodiment, the insulation layer may further include a second membrane provided on the second recess, and defined by a second MEMS hole exposing a portion of an edge of the second recess. In an embodiment, the humidity sensor layer may include a second lower sensor layer on a lower surface of the second membrane, a second middle sensor layer provided on the second lower sensor layer, and provided in the second membrane, and a second upper sensor layer provided on an upper of the second membrane.

In an embodiment of the invention concept, a sensor module includes a substrate having a first region, a second region, and a third region in one direction, and having a first recess in the second region, a lower insulation layer provided on the substrate, a supporting layer provided on the lower insulation layer, a first upper insulation layer provided on the supporting layer, heater electrodes provided on the first upper insulation layer of the second region, a second upper insulation layer provided on the heater electrodes and the first upper insulation layer, lower electrodes provided on the second upper insulation layer, a third upper insulation layer on the lower electrodes and the second upper insulation layer, upper electrodes provided on the third upper insulation layer, a fourth upper insulation layer provided on the upper electrodes of the first region, a gas sensor layer provided on the upper electrodes of the second region, and a humidity sensor layer provided on the upper electrodes of the third region, and being thinner than the gas sensor layer.

In an embodiment, the lower insulation layer, the supporting layer, and the first to fourth upper insulation layers may include a first membrane provided on the first recess, and defined by a first MEMS hole passing through the lower insulation layer, the supporting layer, and the first to fourth upper insulation layers at an edge of the first recess.

In an embodiment, the first membrane may have a first via hole provided on the center of the first recess. In an embodiment, the gas sensor layer may include a first lower sensor layer provided on a lower surface of the lower insulation layer, a first middle sensor layer provided on the first lower sensor layer, and provided in the first via hole, and a first upper sensor layer provided on the first middle sensor layer, the upper electrodes, and the third upper insulation layer.

In an embodiment, the first and second upper insulation layers may include a second recess provided in the third region. In an embodiment, the third upper insulation layer may include a second membrane defined by second MEMS holes exposing an upper surface of the supporting layer at an edge of the second recess, and having at least one second via hole provided on the center of the second recess.

In an embodiment, the humidity sensor layer may include a second lower sensor layer on a lower surface of the second membrane, a second middle sensor layer provided on the second lower sensor layer, and provided in the second via hole, and a second upper sensor layer provided on an upper surface of the second middle sensor layer and an upper surface of the second membrane.

In an embodiment of the inventive concept, a method for manufacturing the sensor module includes forming a lower insulation layer, a supporting layer, and a first upper insulation layer on a substrate having a first region, a second region, and a third region, forming heater electrodes on the first upper insulation layer of the second region, forming a second upper insulation layer on the heater electrodes and the first upper insulation layer, forming lower electrodes on the second upper insulation layer of the first to third regions, forming a third upper insulation layer on the lower electrodes and the second upper insulation layer, forming upper electrodes on the third upper insulation layer of the first to third regions, forming a fourth upper insulation layer on the upper electrodes and the third upper insulation layer of the first region, removing portions of the substrate, the lower insulation layer, the supporting layer, and the first to third upper insulation layers of the second region to form a first MEMS hole, a first via hole, and a first preliminary recess, forming a gas sensor layer in an upper portion of the upper electrodes of the second region, and in the first preliminary recess and the first via hole, further removing a portion of the substrate below the gas sensor layer to form a first recess, and forming a humidity sensor layer on the upper electrodes of the third region.

In an embodiment, the gas sensor layer may include a first lower sensor layer on a lower surface of the lower insulation layer on the first recess, a first middle sensor layer formed in an upper portion of the first lower sensor layer, and formed in the first via hole, and a first upper sensor layer formed on the first middle sensor layer, the upper electrodes, and the third upper insulation layer.

In an embodiment, the method may further include forming a blocking layer on the fourth upper insulation layer of the first region, and on the gas sensor layer of the second region, and removing portions of the second upper insulation layer and the third upper insulation layer of the third region to form a second MEMS hole, a second via hole, and a second preliminary recess. In an embodiment, the humidity sensor layer may be formed inside the second preliminary recess and the second via hole, and on the upper electrodes and the third upper insulation layer.

In an embodiment, the humidity sensor layer may include a second lower sensor layer formed in the second preliminary recess, a second middle sensor layer formed in a lower portion of the second lower sensor layer, and formed in the second via hole, and a second upper sensor layer formed on the second middle sensor layer, the upper electrodes, and the third upper insulation layer.

In an embodiment, the method may further include removing a portion of the first upper insulation layer under the humidity sensor layer to form a second recess, and removing the blocking layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view showing an example of a sensor module according to an embodiment of the inventive concept;

FIG. 2 is a cross-sectional view taken along line I-I′ of FIG. 1;

FIG. 3 is a flowchart showing a method for manufacturing a sensor module of the inventive concept;

FIG. 4 to FIG. 7 are process cross-sectional views showing a method for manufacturing a sensor module according to the inventive concept;

FIG. 8 is a plan view showing an example of a sensor module according to an embodiment of the inventive concept;

FIG. 9 is a cross-sectional view taken along line I-I′ of FIG. 8;

FIG. 10 is a flowchart showing a method for manufacturing a sensor module of the inventive concept; and

FIG. 11 to FIG. 13 are process cross-sectional views showing a method for manufacturing a sensor module according to the inventive concept.

### DETAILED DESCRIPTION

Hereinafter, preferred embodiments of the present invention will be described in detail with reference to the accompanying drawings. Advantages and features of the present invention and methods of accomplishing the same may be understood more readily by reference to the following detailed description of exemplary embodiments and the accompanying drawings. However, the present invention is not limited to the embodiments described herein, and may be embodied in other forms. Rather, the embodiments introduced herein are provided to ensure that the disclosed contents may be thorough and complete, and that the spirit of the present invention may be sufficiently conveyed to those skilled in the art, and the present invention is only defined by the scope of claims. The same reference numerals refer to like elements throughout the specification.

The terms used herein are for the purpose of describing embodiments and are not intended to be limiting of the present invention. In the present specification, singular forms include plural forms unless the context clearly indicates otherwise. As used herein, the terms ‘comprises’ and/or ‘comprising’ are intended to be inclusive of the stated elements, operations and/or devices, and do not exclude the possibility of the presence or the addition of one or more other elements, operations, and/or devices. In addition, since the present specification is according to a preferred embodiment, reference numerals presented according to the order of description are not necessarily limited to the order.

In addition, embodiments described in the present specification will be described with reference to cross-sectional views and/or plan views which are ideal illustrations of the present invention. In the drawings, the thickness of films and regions are exaggerated for an effective description of technical contents. Accordingly, the shape of an exemplary drawing may be modified by manufacturing techniques and/or tolerances. Thus, the embodiments of the present invention are not limited to specific forms illustrated, but are intended to include changes in the form generated by a manufacturing process.

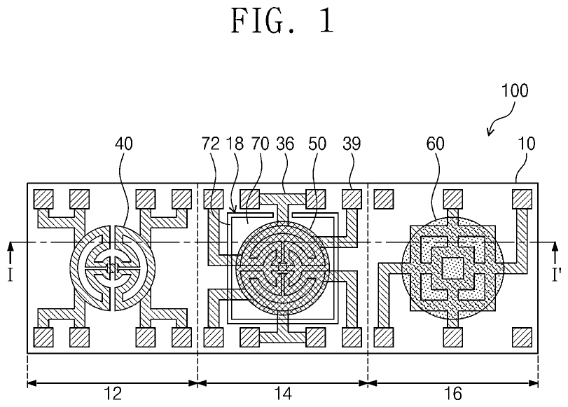

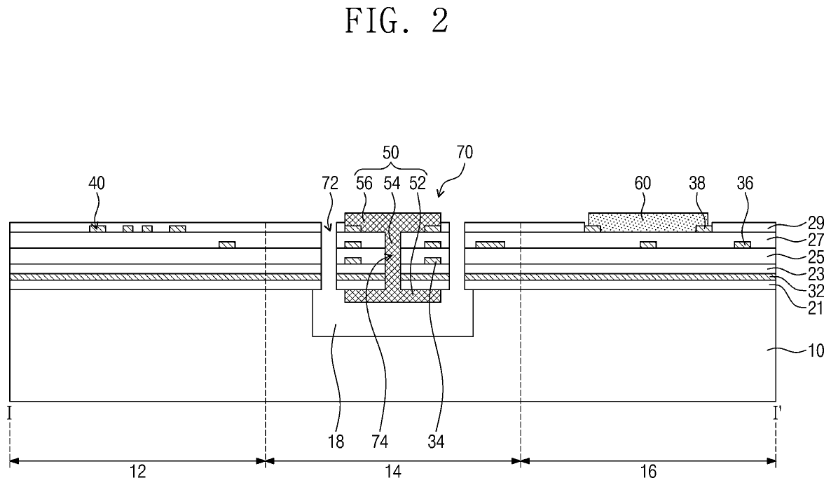

FIG. 1 shows an example of a sensor module 100 according to an embodiment of the inventive concept. FIG. 2 is a cross-sectional view taken along line I-I′ of FIG. 1.

Referring to FIG. 1 and FIG. 2, the sensor module 100 of the present invention may include a broadband hydrogen sensor module or a semiconductor-type hydrogen sensor module. According to an embodiment, the sensor module 100 of the present invention may include a substrate 10, a lower insulation layer 21, a supporting layer 32, a first upper insulation layer 23, heater electrodes 34, a second upper insulation layer 25, lower electrodes 36, a third upper insulation layer 27, upper electrodes 38, a fourth upper insulation layer 29, a gas sensor layer 50, and a humidity sensor layer 60.

The substrate 10 may have a first region 12, a second region 14, and a third region 16. The first region 12, the second region 14, and the third region 16 may be arranged in one direction. The first region 12 may be a temperature sensing region. The second region 14 may be provided at one side of the first region 12. The second region 14 may be a gas sensing region. The substrate 10 of the second region 14 may have a first recess 18. The first recess 18 may be provided in the center of the second region 14. The third region 16 may be provided at one side of the second region 14. The third region 16 may be a humidity sensing region. For example, the substrate 10 may include a silicon wafer, aluminum oxide (Al2O3), magnesium oxide (MgO), quartz, gallium-nitrogen (GaN), and gallium-arsenide (GaAs). Alternatively, the substrate 10 may include a flexible substrate made of such as polycarbonate (PC), polyethyleneterephthalate (PET), polyethersulfone (PES), polyethylenenaphthalate (PEN), or polyimide (PI), but the embodiment of the inventive concept is not limited thereto.

The lower insulation layer 21 may be provided on the substrate 10. For example, the lower insulation layer 21 may include silicon oxide, silicon nitride, or silicon nitride. Alternatively, the lower insulation layer 21 may include a polymer, but the embodiment of the inventive concept is not limited thereto.

The supporting layer 32 may be provided on the lower insulation layer 21. The supporting layer 32 may include a spring or a plastic layer. Alternatively, the supporting layer 32 may include a metal such as gold (Au), silver (Ag), copper (Cu), aluminum (Al), or tungsten (W), but the embodiment of the inventive concept is not limited thereto.

The first upper insulation layer 23 may be provided on the supporting layer 32. The first upper insulation layer 23 may include the same material as that of the lower insulation layer 21. The first upper insulation layer 23 may include silicon oxide, silicon nitride, or silicon nitride. Alternatively, the first upper insulation layer 23 may include a polymer, but the embodiment of the inventive concept is not limited thereto.

The heater electrodes 34 may be provided on the first upper insulation layer 23 of the second region 14. The heater electrodes 34 may have an inter-digital or gap shape. The heater electrodes 34 may heat the gas sensor layer 50 provided in an upper portion thereof. The heater electrodes 34 may include an alloy of chromium (Cr) and nickel (Ni). Alternatively, the heater electrodes 34 may include a metal such as tungsten (W), platinum (Pt), or palladium (Pd), silicon, or a conductive metal oxide, but the embodiment of the inventive concept is not limited thereto.

The second upper insulation layer 25 may be provided on the heater electrodes 34 and the first upper insulation layer 23. The second upper insulation layer 25 may include the same material as that of the lower insulation layer 21 and the first upper insulation layer 23. The second upper insulation layer 25 may include silicon oxide, silicon nitride, or silicon nitride. Alternatively, the lower insulation layer 21 may include a polymer, but the embodiment of the inventive concept is not limited thereto.

The lower electrodes 36 may be provided on the second upper insulation layer 25. The lower electrodes 36 may be lines or line electrodes connected to the upper electrodes 38. The lower electrodes 36 may connect the upper electrodes 38 to pads 39. The pads 39 may be provided at an edge of each of the first region 12, the second region 14, and the third region 16.

The third upper insulation layer 27 may be provided on the lower electrodes 36 and the second upper insulation layer 25. The third upper insulation layer 27 may include silicon oxide, silicon nitride, or silicon nitride. Alternatively, the third upper insulation layer 27 may include a polymer, but the embodiment of the inventive concept is not limited thereto.

The upper electrodes 38 may be provided on the third upper insulation layer 27. The upper electrodes 38 may be provided in the first region 12, the second region 14, and the third region 16. The upper electrodes 38 of the first region 12 may be a temperature sensor layer 40. The temperature sensor layer 40 may sense the temperature of the substrate 10 and the outside of the substrate 10. Temperature information may be used to correct a gas concentration error of the gas sensor layer 50. For example, the upper electrodes 38 may include a metal such as gold (Au), silver (Ag), aluminum (AI), tungsten (W), molybdenum (Mo), cobalt (Co), nickel (Ni), chromium (Cr), or platinum (Pt), but the embodiment of the inventive concept is not limited thereto.

The fourth upper insulation layer 29 may be provided on the temperature sensor layer 40 and the third upper insulation layer 27. The fourth upper insulation layer 29 may selectively expose the upper electrodes 38 of the second region 14 and the third region 16. The fourth upper insulation layer 29 may include silicon oxide, silicon nitride, or silicon nitride. Alternatively, the fourth upper insulation layer 29 may include a resin or polymer, but the embodiment of the inventive concept is not limited thereto.

First MEMS holes 72 may be provided on both outer sides of the upper electrodes 38 of this second region 14. The first MEMS holes 72 may expose a portion of the substrate 10 at the bottom of the first recess 18. The first MEMS hole 72 may define a first membrane 70. That is, the lower insulation layer 21, the supporting layer 32, the first upper insulation layer 23, the second upper insulation layer 25, the third upper insulation layer 27, and the fourth upper insulation layer 29 of the second region 14 may include the first membrane 70. The first membrane 70 may be a MEMS membrane. The first membrane 70 may include the lower insulation layer 21, the supporting layer 32, the first upper insulation layer 23, the second upper insulation layer 25, the third upper insulation layer 27, and the fourth upper insulation layer 29 between the first MEMS holes 72 of the second region 14.

A first via hole 74 may be provided in the center of the first membrane 70. The first via hole 74 may penetrate the center of the lower insulation layer 21, the supporting layer 32, the first upper insulation layer 23, the second upper insulation layer 25, the third upper insulation layer 27, and the fourth upper insulation layer 29 of the first membrane 70. The first via hole 74 may be provided between each of the heater electrodes 34 and the lower electrodes.

The gas sensor layer 50 may be provided in the second region 14. The gas sensor layer 50 may be thicker than the temperature sensor layer 40 in the first region 12. The gas sensor layer 50 may be provided on an upper surface and a lower surface of the first membrane 70. The gas sensor layer 50 may be provided in the first via hole 74. The gas sensor layer 50 may be provided on the upper electrodes 38 and the third upper insulation layer 27 of the second region 14. The gas sensor layer 50 may be provided on a lower surface of the lower insulation layer 21. The gas sensor layer 50 may penetrate the lower insulation layer 21, the first upper insulation layer 23, the second upper insulation layer 25, and the third upper insulation layer 27 through the first via hole 74. For example, the gas sensor layer 50 may have an I-shape from a vertical viewpoint. The gas sensor layer 50 may sense a hydrogen gas in the atmosphere. The gas sensor layer 50 may include a metal or a metal oxide. The gas sensor layer 50 may include gold (Au), tungsten (W), platinum (Pt), or palladium (Pd), but the embodiment of the inventive concept is not limited thereto. According to an example, the gas sensor layer 50 may include a first lower sensor layer 52, a first middle sensor layer 54, and a first upper sensor layer 56. The first lower sensor layer 52 may be provided on the lower surface of the lower insulation layer 21. The first middle sensor layer 54 may be provided on the first lower sensor layer 52. The first middle sensor layer 54 may be provided in the first via hole 74. The first upper sensor layer 56 may be provided on the first middle sensor layer 54. The first upper sensor layer 56 may be provided on the upper electrodes 38 and the third upper insulation layer 27.

The humidity sensor layer 60 may be provided on the upper electrodes 38 of the third region 16. The humidity sensor layer 60 may be thinner than the gas sensor layer 50 and thicker than the temperature sensor layer 40. The humidity sensor layer 60 may sense humidity. Humidity information may be used to correct a gas concentration error of the gas sensor layer 50. For example, the humidity sensor layer 60 may include polyimide, graphene, carbon nanotube (CNT), or a mixture thereof. Alternatively, the humidity sensor layer 60 may include a metal oxide such as MgCO, TiO, ZrO2, or CeO2, but the embodiment of the inventive concept is not limited thereto.

Therefore, the sensor module 100 of the present invention may increase or maximize the reliability of gas sensing by correcting a gas concentration error of the gas sensor layer 50 by using temperature information and humidity information of the temperature sensor layer 40 and the humidity sensor layer 60.

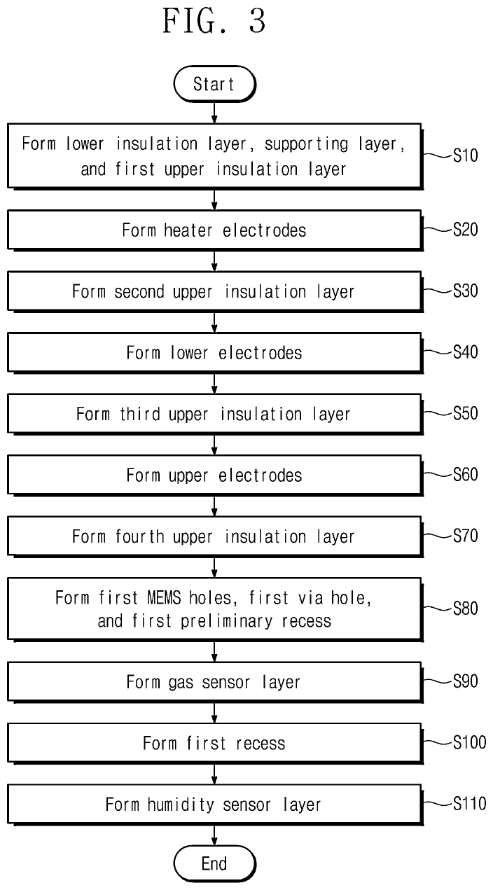

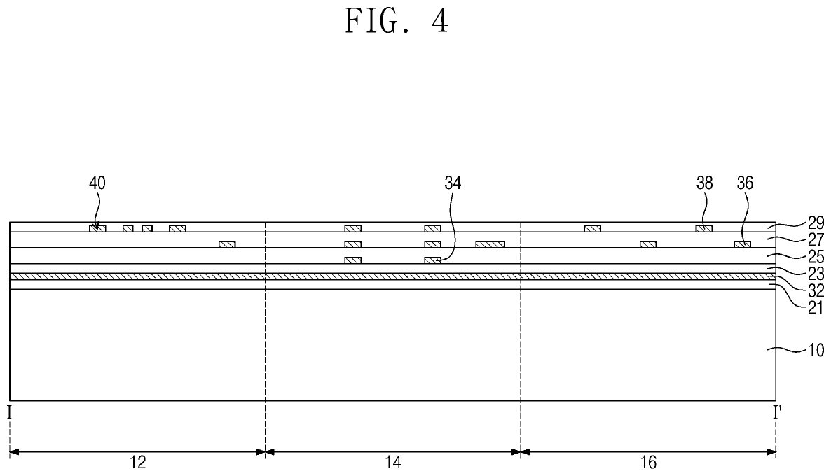

FIG. 3 shows an example of a method for manufacturing the sensor module 100 of the present invention. FIGS. 4 to 7 are process cross-sectional views of the sensor module 100 of the present invention.

Referring to FIG. 3 and FIG. 4, a lower insulation layer 21, a supporting layer 32, and a first upper insulation layer 23 are formed on a substrate 10 S10. The lower insulation layer 21 may include silicon oxide, silicon nitride, or silicon oxynitride formed by a physical vapor deposition method or a chemical vapor deposition method. The supporting layer 32 may include a spring or a plastic layer formed by a spin coating method, a sol-gel method, a melting method, or a chemical vapor deposition method. The first upper insulation layer 23 may include silicon oxide, silicon nitride, or silicon oxynitride formed by a physical vapor deposition method or a chemical vapor deposition method.

Next, heater electrodes 34 are formed on the first upper insulation layer 23 of a second region 14 S20. The heater electrodes 34 may be formed by a metal deposition process, a lithography process, and an etching process. The heater electrodes 34 may include an alloy of chromium (Cr) and nickel (Ni).

Thereafter, a second upper insulation layer 25 is formed on the heater electrodes 34 and the first upper insulation layer 23 S30. The second upper insulation layer 25 may include silicon oxide, silicon nitride, or silicon oxynitride formed by a physical vapor deposition method or a chemical vapor deposition method.

Thereafter, lower electrodes 36 are formed on the second upper insulation layer 25 of a first region 12, a second region 14, the third region 16 S40. The lower electrodes 36 may include a metal formed through a metal deposition process, a lithography process, and an etching process. The lower electrodes 36 may include a metal such as gold (Au), silver (Ag), aluminum (Al), tungsten (W), molybdenum (Mo), cobalt (Co), nickel (Ni), chromium (Cr), or platinum (Pt), but the embodiment of the inventive concept is not limited thereto.

Thereafter, a third upper insulation layer 27 is formed on the lower electrodes 36 and the second upper insulation layer 25 S50. The third upper insulation layer 27 may include silicon oxide, silicon nitride, or silicon oxynitride formed by a physical vapor deposition method or a chemical vapor deposition method. The third upper insulation layer 27 may be removed from the lower electrodes 36 to expose a portion of the lower electrodes 36.

Next, upper electrodes 38 are formed on the third upper insulation layer 27 of the first region 12, the second region 14, and the third region 16 S60. The upper electrodes 38 may be formed by a metal deposition process, a lithography process, and an etching process. The metal deposition process may include a physical vapor deposition method such as a sputtering deposition method, an electron beam deposition method, or a vaporization deposition method. The upper electrodes 38 may include a metal such as gold (Au), silver (Ag), aluminum (Al), tungsten (W), molybdenum (Mo), cobalt (Co), nickel (Ni), chromium (Cr), or platinum (Pt), but the embodiment of the inventive concept is not limited thereto. The upper electrodes 38 may be connected to the lower electrodes 36. According to an example, the upper electrode 38 of the first region 12 may be a temperature sensing layer 40.

Then, a fourth upper insulation layer 29 is formed on the upper electrodes 38 and the third upper insulation layer 27 S70. The fourth upper insulation layer 29 may include silicon oxide, silicon nitride, or silicon oxynitride formed by a physical vapor deposition method or a chemical vapor deposition method.

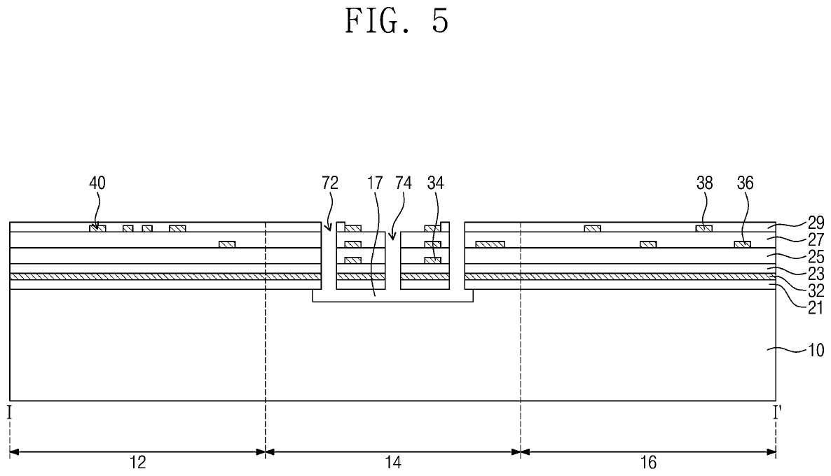

Referring to FIG. 3 and FIG. 5, portions of the substrate 10, the lower insulation layer 21, the supporting layer 32, the first upper insulation layer 23, the second upper insulation layer 25, the third upper insulation layer 27, and the fourth upper insulation layer 29 of the second region 14 are removed to form first MEMS holes 72, a first via hole 74, and a first preliminary recess 17 S80. The lower insulation layer 21, the supporting layer 32, the first upper insulation layer 23, the second upper insulation layer 25, the third upper insulation layer 27, and the fourth upper insulation layer 29 may be removed by a dry etching method. An etching gas of the dry etching method may include a XeF₂ gas. The substrate 10 may be removed by a wet etching method. The first MEMS holes 72 may be formed at an edge of the second region 14 to define the first membrane 70. The first MEMS holes 72 may expose an upper surface of the edge of the second region 14. The first via hole 74 may be formed in the center of the first membrane 70. The first via hole 74 may expose an upper surface of the substrate 10 in the center of the second region 14. The first preliminary recess 17 may be formed between the substrate 10 and the lower insulation layer 21 by a wet etchant provided in the first MEMS holes 72 and the first via hole 74.

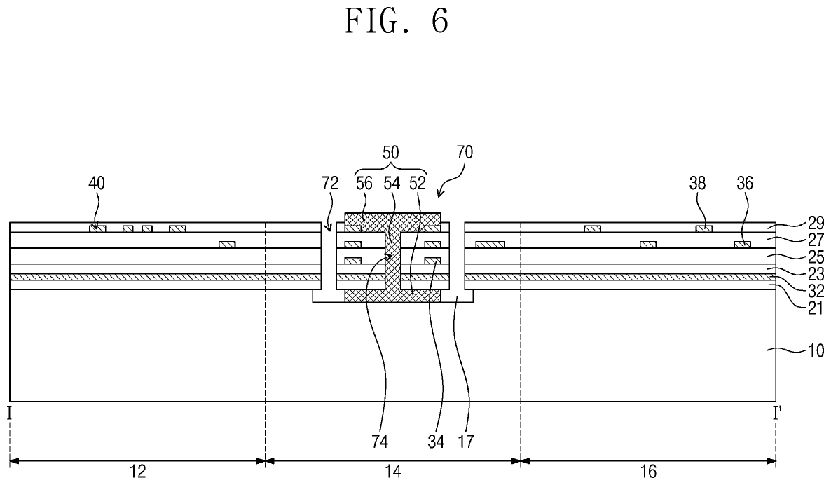

Referring to FIG. 3 and FIG. 6, a gas sensor layer 50 is formed on an upper surface of the upper electrodes 38 and the third upper insulation layer 27, and in the first via hole 74, and the first preliminary recess 17 S90. The gas sensor layer 50 may include a metal or a metal oxide formed by a screen printing process and an inkjet printing process. Alternatively, the gas sensor layer 50 may include a metal oxide formed by a physical vapor deposition method, a lithography process, and an etching process. For example, the gas sensor layer 50 may include gold (Au), tungsten (W), platinum (Pt), or palladium (Pd), but the embodiment of the inventive concept is not limited thereto.

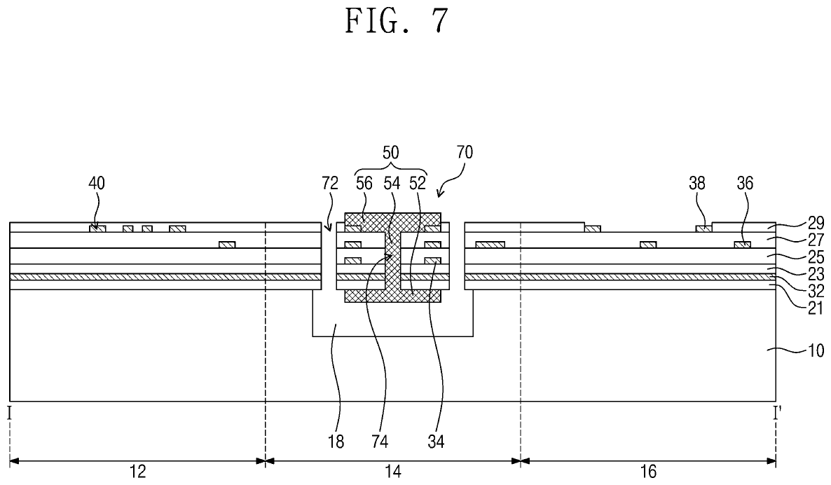

Referring to FIG. 3 and FIG. 7, a portion of the substrate 10 of the second region 14 is further removed to form a first recess 18 or a first cavity S100. The first recess 18 may be larger and wider than the first preliminary recess 17. The first recess 18 may be formed by a wet etching method of the substrate 10.

Next, a portion of the fourth upper insulation layer 29 of the third region 16 is removed to expose the upper electrode 38 and a portion of the third upper insulation layer 27 between the upper electrodes 38.

Referring to FIG. 2 and FIG. 3, a humidity sensor layer 60 is formed on the upper electrodes 38 and the third upper insulation layer 27 of the third region 16 S110. For example, the humidity sensor layer 60 may include a metal oxide formed by a screen printing method or an inkjet printing method. Alternatively, the humidity sensor layer 60 may be formed through a metal deposition process, a lithography process, and an etching process. The humidity sensor layer 60 may include polyimide, graphene, carbon nanotube (CNT), or a mixture thereof, but the embodiment of the inventive concept is not limited thereto.

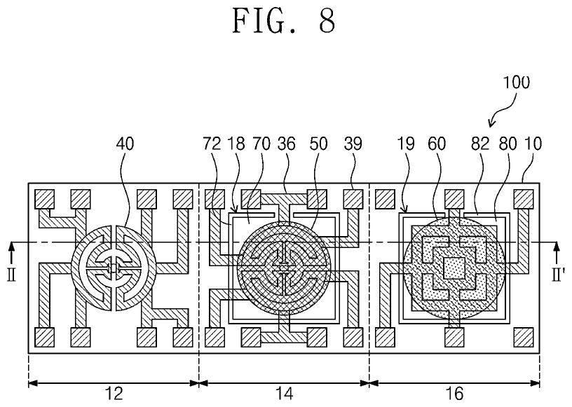

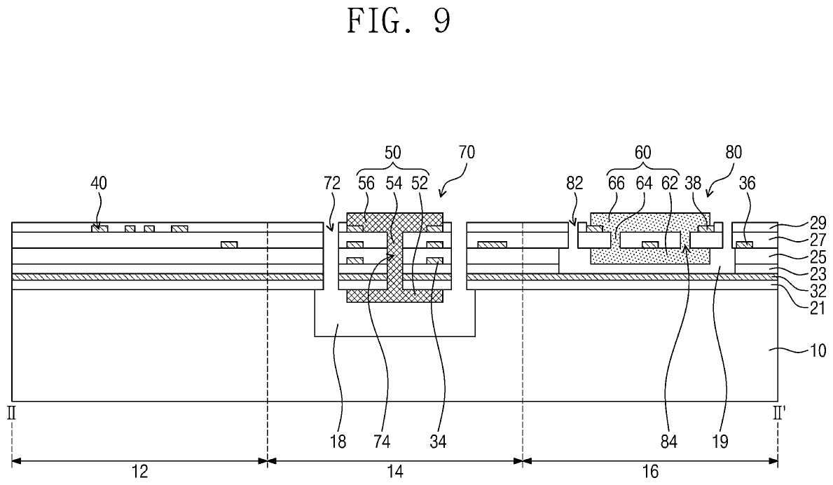

FIG. 8 shows an example of a sensor module 100 according to an embodiment of the inventive concept. FIG. 9 shows a view taken along line II-II′ of FIG. 8.

Referring to FIG. 8 and FIG. 9, a second recess 19 of the third region 16 and a second membrane 80 in the second recess 19 may be further included. The second recess 19 may be higher than the first recess 18. The second recess 19 may include a second cavity provided in the first upper insulation layer 23 and the second upper insulation layer 25 of the third region 16.

The third upper insulation layer 27 and the fourth upper insulation layer 29 of the third region 16 may include the second membrane 80 on the second recess 19. The second membrane 80 may be provided inside and in an upper portion of the second recess 19. The second membrane 80 may be defined by a second MEMS hole 82 on an edge of the second recess 19. The second MEMS hole 82 may expose a portion of the upper surface of the supporting layer 32 at the bottom of the second recess 19. The second MEMS hole 82 may pass through the third upper insulation layer 27 and the fourth upper insulation layer 29. That is, the third upper insulation layer 27 and the fourth upper insulation layer 29 of the third region 16 may include the second membrane 80.

The second membrane 80 may be thinner than the first membrane 70. The second membrane 80 may include the third upper insulation layer 27 of the third region 16 and a second via hole 84 in the center of the third upper insulation layer 27.

The humidity sensor layer 60 may be provided on an upper surface and a lower surface of the third upper insulation layer 27. The humidity sensor layer 60 may be provided in the second via hole 84. The humidity sensor layer 60 may have an II-shape from a vertical viewpoint. According to an example, the humidity sensor layer 60 may include a second lower sensor layer 62, a second middle sensor layer 64, and a second upper sensor layer 66. The second lower sensor layer 62 may be provided on a lower surface of the third upper insulation layer 27. The second middle sensor layer 64 may be provided on the second lower sensor layer 62. The second middle sensor layer 64 may be provided in the second via hole 84. The second upper sensor layer 66 may be provided on the second middle sensor layer 64, the upper electrodes 38, and the third upper insulation layer 27.

The substrate 10, the lower insulation layer 21, the supporting layer 32, the heater electrodes 34, the temperature sensor layer 40, the gas sensor layer 50, and the first membrane 70 may be configured in the same manner as shown in FIG. 1 and FIG. 2.

A method for manufacturing the sensor module 100 of the present invention configured as described above will be described as follows.

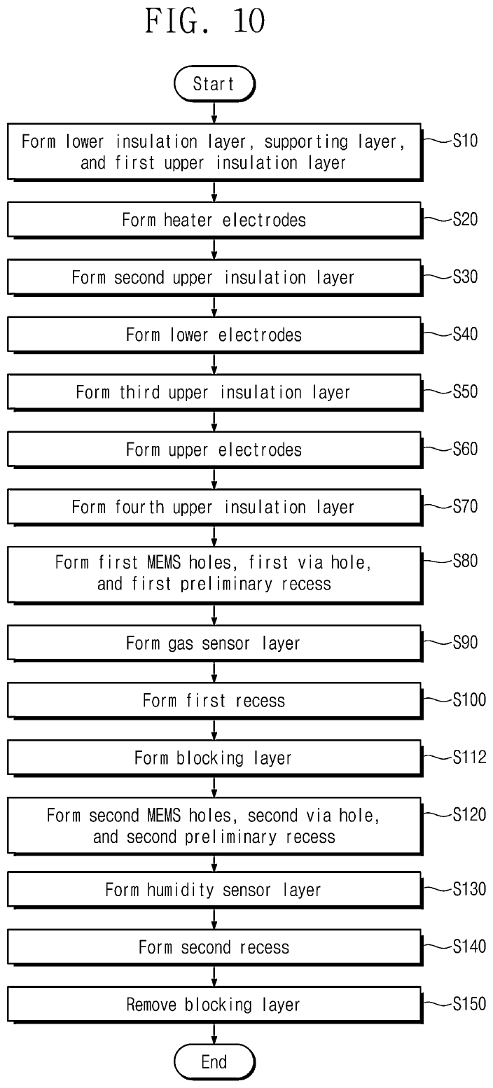

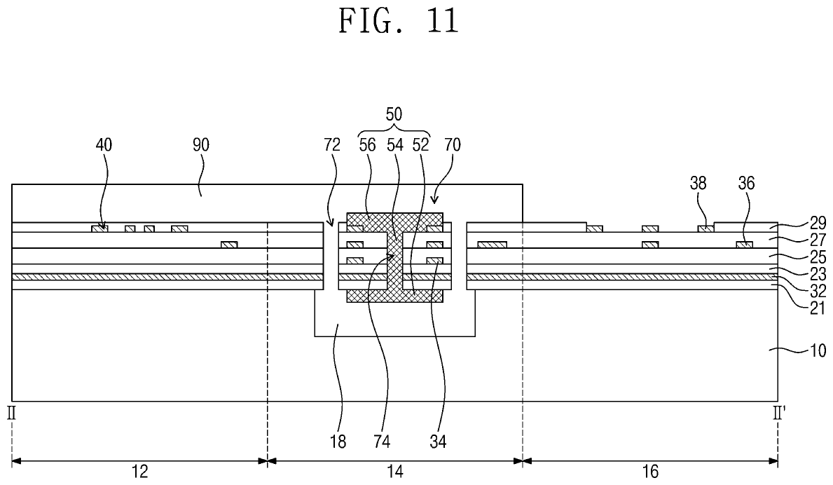

FIG. 10 shows an example of a method for manufacturing the sensor module 100 of the present invention. FIGS. 11 to 13 are process cross-sectional views of the sensor module 100 of the present invention.

Referring to FIG. 4 and FIG. 10, a lower insulation layer 21, a supporting layer 32, and a first upper insulation layer 23 are formed on a substrate 10 S10.

Next, heater electrodes 34 are formed on the first upper insulation layer 23 of a second region 14 S20.

Thereafter, a second upper insulation layer 25 is formed on the heater electrodes 34 and the first upper insulation layer 23 S30.

Thereafter, lower electrodes 36 are formed on the second upper insulation layer 25 of a first region 12, a second region 14, and a third region 16 S40.

Thereafter, a third upper insulation layer 27 is formed on the lower electrodes 36 and the second upper insulation layer 25 S50. The third upper insulation layer 27 may include a material different from that of the first upper insulation layer 23 and the second upper insulation layer 25. That is, the third upper insulation layer 27 may have an etch selectivity with respect to the first upper insulation layer 23 and the second upper insulation layer 25. If the first upper insulation layer 23 and the second upper insulation layer 25 are each silicon oxide, the third upper insulation layer 27 may include silicon nitride. If the first upper insulation layer 23 and the second upper insulation layer 25 are each silicon nitride, the third upper insulation layer 27 may include silicon oxide.

Next, upper electrodes 38 are formed on the third upper insulation layer 27 of the first region 12, the second region 14, and the third region 16 S60.

Then, a fourth upper insulation layer 29 is formed on the upper electrodes 38 and the third upper insulation layer 27 S70. The fourth upper insulation layer 29 may include a material different from that of the first upper insulation layer 23, the second upper insulation layer 25, and the third upper insulation film 27. The fourth upper insulation layer 29 may include a polymer, but the embodiment of the inventive concept is not limited thereto.

Referring to FIG. 5 and FIG. 10, portions of the substrate 10, the lower insulation layer 21, the supporting layer 32, the first upper insulation layer 23, the second upper insulation layer 25, the third upper insulation layer 27, and the fourth upper insulation layer 29 of the second region 14 are removed to form first MEMS holes 72, a first via hole 74, and a first preliminary recess 17 S80.

Referring to FIG. 6 and FIG. 10, a gas sensor layer 50 is formed on an upper surface of the upper electrodes 38 and the third upper insulation layer 27, and in the first via hole 74, and the first preliminary recess 17 S90. A portion of the fourth upper insulation layer 29 of the third region 16 may be removed, and the upper electrodes 38 and the third upper insulation layer 27 of the third region 16 may be exposed.

Referring to FIG. 7 and FIG. 10, a portion of the substrate 10 of the second region 14 is further removed to form a first recess 18 or a first cavity S100.

Referring to FIG. 10 and FIG. 11, a blocking layer 90 is formed on a temperature sensor layer 40 and a gas sensor layer 50 of the first region 12 and the second region 14 S112. The blocking layer 90 may include a polymer or paraffin. The fourth upper insulation layer 29 of the third region 16 may be exposed from the blocking layer 90.

Next, a portion of the fourth upper insulation layer 29 of the third region 16 may be removed to expose the upper electrode 38 and a portion of the third upper insulation layer 27 between the upper electrodes 38. The fourth upper insulation layer 29 may be removed by a lithography process and an etching process.

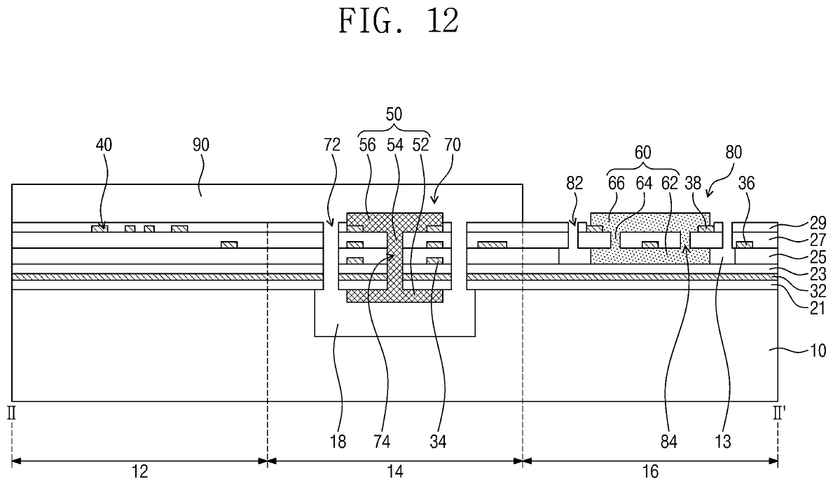

Referring to FIG. 10 and FIG. 12, portions of the second upper insulation layer 25, the third upper insulation layer 27, and the fourth upper insulation layer 29 of the third region 16 are removed to form a second MEMS hole 82, a second via hole 84, and a second preliminary recess 13 S120. The second upper insulation layer 25, the third upper insulation layer 27, and the fourth upper insulation layer 29 may be removed by a lithography process and an etching process. The second MEMS hole 82 may expose a portion of the first upper insulation layer 23 at an edge of the second preliminary recess 13, and may define the second membrane 80 of the third upper insulation layer 27 and the fourth upper insulation layer 29.

Next, the humidity sensor layer 60 is formed on a lower surface and an upper surface of the second membrane 80, and in the second via hole 84 S130. The humidity sensor layer 60 may include a metal oxide formed by a screen printing method or an inkjet printing method. The humidity sensor layer 60 may include a second lower sensor layer 62, a second middle sensor layer 64, and a second upper sensor layer 66. The second lower sensor layer 62 may be formed on a lower surface of the third upper insulation layer 27. The second middle sensor layer 64 may be form on the second lower sensor layer 62. The second middle sensor layer 64 may be provided in the second via hole 84. The second upper sensor layer 66 may be formed on the second middle sensor layer 64, the upper electrodes 38, and the third upper insulation layer 27.

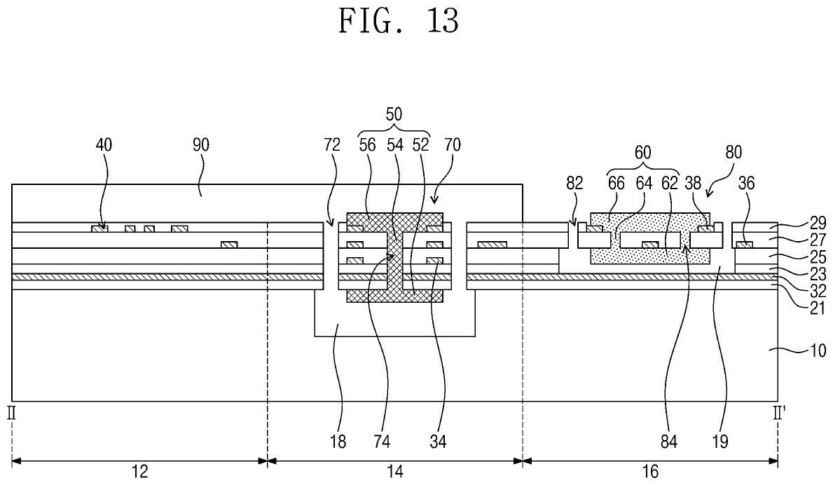

Referring to FIG. 10 and FIG. 13, a portion of the first upper insulation layer 23 at the bottom of the second preliminary recess 13 may be removed to form a second recess 19 or a second cavity S140. The first upper insulation layer 23 may be removed by a wet etching method.

Referring to FIG. 9 and FIG. 13, the blocking layer 90 is removed S150. The blocking layer 90 may be removed by using an organic solvent.

As described above, a sensor module according to an embodiment of the present invention may increase or maximize the reliability of gas sensing by correcting a gas concentration error by using temperature information and humidity information of a temperature sensor layer and a humidity sensor layer provided on both sides of a gas sensor layer.

Although the embodiments of the present invention have been described with reference to the accompanying drawings, those skilled in the art will understand that the present invention can be implemented in other specific forms without changing the technical spirit or essential features thereof. Therefore, the embodiments described above should be understood as illustrative in all respects and not restrictive.

What is claimed is:

1. A sensor module comprising:
a substrate having a first region, a second region, and a third region;
an insulation layer provided on the substrate;
a temperature sensor layer provided in the insulation layer of the first region;
a gas sensor layer provided in an upper portion of and inside the insulation layer of the second region adjacent to the temperature sensor layer, and being thicker than the temperature sensor layer; and
a humidity sensor layer provided on the insulation layer of the third region adjacent to the gas sensor layer, the humidity sensor layer thinner than the gas sensor layer.

2. The sensor module of claim 1, wherein the substrate has a first recess provided in the second region, wherein the gas sensor layer is provided in the first recess.

3. The sensor module of claim 2, wherein the insulation layer comprises a first membrane provided on the first recess, and defined by a first MEMS hole exposing a portion of an edge of the first recess,
wherein the sensor module further includes:
heater electrodes provided in the first membrane;
lower electrodes provided in the first membrane on the heater electrodes; and
upper electrodes provided in the first membrane on the lower electrodes.

4. The sensor module of claim 3, wherein the gas sensor layer comprises:
a first lower sensor layer on a lower surface of the first membrane; and
a first upper sensor layer on an upper surface of the first membrane.

5. The sensor module of claim 4, wherein the first membrane has a first via hole provided on the center of the first recess.

6. The sensor module of claim 5, wherein the gas sensor layer further comprises a first middle sensor layer provided in the first via hall.

7. The sensor module of claim 3, further comprising a supporting layer provided between the substrate and the lower electrodes.

8. The sensor module of claim 1, wherein the insulation layer has a second recess provided in the third region.

9. The sensor module of claim 8, wherein the humidity sensor layer is provided in the second recess.

10. The sensor module of claim 9, wherein the insulation layer further comprises a second membrane provided on the second recess, and defined by a second MEMS hole exposing a portion of an edge of the second recess,
wherein the humidity sensor layer includes:
a second lower sensor layer on a lower surface of the second membrane;
a second middle sensor layer provided on the second lower sensor layer, and provided in the second membrane; and
a second upper sensor layer provided on an upper of the second membrane.

11. A sensor module comprising:
a substrate having a first region, a second region, and a third region in one direction, and having a first recess in the second region;
a lower insulation layer provided on the substrate;
a supporting layer provided on the lower insulation layer;
a first upper insulation layer provided on the supporting layer;
heater electrodes provided on the first upper insulation layer of the second region;
a second upper insulation layer provided on the heater electrodes and the first upper insulation layer;
lower electrodes provided on the second upper insulation layer;
a third upper insulation layer on the lower electrodes and the second upper insulation layer;
upper electrodes provided on the third upper insulation layer;
a fourth upper insulation layer provided on the upper electrodes of the first region;
a gas sensor layer provided on the upper electrodes of the second region; and
a humidity sensor layer provided on the upper electrodes of the third region, and being thinner than the gas sensor layer.

12. The sensor module of claim 11, wherein the lower insulation layer, the supporting layer, and the first to fourth upper insulation layers comprise a first membrane provided on the first recess, and defined by a first MEMS hole passing through the lower insulation layer, the supporting layer, and the first to fourth upper insulation layers at an edge of the first recess.

13. The sensor module of claim 12, wherein the first membrane has a first via hole provided on the center of the first recess,
wherein the gas sensor layer comprises:
a first lower sensor layer provided on a lower surface of the lower insulation layer;
a first middle sensor layer provided on the first lower sensor layer, and provided in the first via hole; and
a first upper sensor layer provided on the first middle sensor layer, the upper electrodes, and the third upper insulation layer.

14. The sensor module of claim 11, wherein the first and second upper insulation layers comprise a second recess provided in the third region, wherein the third upper insulation layer includes a second membrane defined by second MEMS holes exposing an upper surface of the supporting layer at an edge of the second recess, the second membrane having at least one second via hole provided on the center of the second recess.

15. The sensor module of claim 14, wherein the humidity sensor layer comprises:
a second lower sensor layer on a lower surface of the second membrane;
a second middle sensor layer provided on the second lower sensor layer, and provided in the second via hole; and
a second upper sensor layer provided on an upper surface of the second middle sensor layer and an upper surface of the second membrane.

16. A method for manufacturing a sensor module, the method comprising:
forming a lower insulation layer, a supporting layer, and a first upper insulation layer on a substrate having a first region, a second region, and a third region;
forming heater electrodes on the first upper insulation layer of the second region;
forming a second upper insulation layer on the heater electrodes and the first upper insulation layer;
forming lower electrodes on the second upper insulation layer of the first to third regions;
forming a third upper insulation layer on the lower electrodes and the second upper insulation layer;
forming upper electrodes on the third upper insulation layer of the first to third regions;
forming a fourth upper insulation layer on the upper electrodes and the third upper insulation layer of the first region;
removing portions of the substrate, the lower insulation layer, the supporting layer, and the first to third upper insulation layers of the second region to form a first MEMS hole, a first via hole, and a first preliminary recess;
forming a gas sensor layer in an upper portion of the upper electrodes of the second region, and in the first preliminary recess and the first via hole;
further removing a portion of the substrate below the gas sensor layer to form a first recess; and
forming a humidity sensor layer on the upper electrodes of the third region.

17. The method of claim 16, wherein the gas sensor layer comprises:
a first lower sensor layer on a lower surface of the lower insulation layer on the first recess;
a first middle sensor layer formed in an upper portion of the first lower sensor layer, and formed in the first via hole; and
a first upper sensor layer formed on the first middle sensor layer, the upper electrodes, and the third upper insulation layer.

18. The method of claim 16, further comprising:
forming a blocking layer on the fourth upper insulation layer of the first region, and on the gas sensor layer of the second region; and
removing portions of the second upper insulation layer and the third upper insulation layer of the third region to form a second MEMS hole, a second via hole, and a second preliminary recess,
wherein the humidity sensor layer is formed inside of the second preliminary recess and the second via hole, and on the upper electrodes and the third upper insulation layer.

19. The method of claim 18, wherein the humidity sensor layer comprises:
a second lower sensor layer formed in the second preliminary recess;
a second middle sensor layer formed in a lower portion of the second lower sensor layer, and formed in the second via hole; and
a second upper sensor layer formed on the second middle sensor layer, the upper electrodes, and the third upper insulation layer.

20. The method of claim 18, further comprising:
removing a portion of the first upper insulation layer under the humidity sensor layer to form a second recess; and
removing the blocking layer.
